(19) United States
(12) Patent Application Publication
(10) Pub. No.: US 2015/0091152 A1
(43) Pub. Date: Apr. 2, 2015

(54) EXTERNAL CONNECTION TERMINAL, SEMICONDUCTOR PACKAGE HAVING EXTERNAL CONNECTION TERMINAL AND METHOD OF MANUFACTURING THE SAME

(71) Applicant: SAMSUNG ELECTRO-MECHANICS CO., LTD., Suwon-Si (KR)

(72) Inventors: Eun Jung JO, Suwon-Si (KR); Chang Seob HONG, Suwon-Si (KR); Kyu Hwan OH, Suwon-Si (KR); Kang Hyun LEE, Suwon-Si (KR)

(73) Assignee: SAMSUNG ELECTRO-MECHANICS CO., LTD., Suwon-Si (KR)

(21) Appl. No.: 14/491,906

(22) Filed: Sep. 19, 2014

(30) Foreign Application Priority Data
Oct. 2, 2013 (KR) 10-2013-0117930

(51) Int. Cl. H01L 23/00; H05K 1/09

(52) U.S. Cl. CPC H01L 24/13; H01L 24/05; H01L 24/81; H01L 24/48; H01L 24/85; H01L 24/43; H05K 1/09; H01L 2924/01079; H01L 2924/01029; H01L 2924/01013; H01L 2924/01047; H01L 2224/48505; H01L 2224/81801
USPC 257/693; 29/846; 438/118; 174/251

(57) ABSTRACT

Disclosed herein are an external connection terminal, a semiconductor package having the external connection terminal, and a method of manufacturing the same. The external connection terminal includes an internal insulating material, an external insulating material formed to enclose the internal insulating material, and metal lines formed between the internal insulating material and the external insulating material.

### CROSS REFERENCE TO RELATED APPLICATION

This application claims the benefit of Korean Patent Application No. 10-2013-0117930, filed on Oct. 2, 2013, entitled “External Connection Terminal, Semiconductor Package Having External Connection Terminal And Method Of Manufacturing The Same” which is hereby incorporated by reference in its entirety into this application.

### BACKGROUND OF THE INVENTION

1. Technical Field

The present invention relates to an external connection terminal, a semiconductor package having the external connection terminal, and a method of manufacturing the same.

2. Description of the Related Art

Recently, electronic devices tend to be designed in a packaging form and have a package structure so to be easily subminiature, such that the electronic devices may perform multi-function with a minimum area by having a large number of semiconductor chips packaged on a mother board of a cellular phone, a smart phone, a tablet PC, a notebook, and the like. Therefore, a semiconductor chip is highly integrated and is being developed to a semiconductor package which is systematized and integrated into one module and a size of the package is reduced and a mounting density thereof is also increased. Since the package is light, thin, short, and small and is high performance and systematization, a method of integrating various packages has been emerged to implement a package having various functions into one package.

As the traditional technologies applied to a double-sided packaging product, a technology of implementing an I/O terminal of a package by connecting a copper pin to a lower surface of the substrate with soldering, a technology of implementing an I/O terminal by molding a lower surface, penetrating the mold through a terminal of a printed circuit board by using a laser drill, and filling a through hole with a conductive material, and the like have been developed. However, to apply the technology, a complicated package process is required, which causes a tolerance.

### PRIOR ART DOCUMENT

### Patent Document

(Patent Document 1) Japanese Patent Laid-Open Publication No. 2013-58516

### SUMMARY OF THE INVENTION

The present invention has been made in an effort to provide an external connection terminal which is separately formed on a lower portion of a package and is thus attached to a substrate, a semiconductor package having the external connection terminal, and a method of manufacturing the same.

According to a preferred embodiment of the present invention, there is provided an external connection terminal, including: an internal insulating material; an external insulating material formed to enclose the internal insulating material; and metal lines formed between the internal insulating material and the external insulating material.

The metal lines may be formed to be exposed on upper and lower surfaces of the internal insulating material and the external insulating material.

The metal line may be made of copper, aluminum, silver, or gold.

The internal insulating material and the external insulating material may be made of different materials.

According to another preferred embodiment of the present invention, there is provided a method of manufacturing an external connection terminal including: preparing an internal insulating material; forming metals line on the internal insulating material; and forming an external insulating material to enclose the internal insulating material and the metal lines.

The method of manufacturing an external connection terminal may further include: after the forming of the external insulating material, polishing the metal lines to be exposed on upper and lower surfaces of the internal insulating material and the external insulating material.

The forming of the metal lines on the internal insulating material may include performing coiling.

The method of manufacturing an external connection terminal may further include: after the forming of the external insulating material, cutting the internal insulating material and the external insulating material in a plurality of units.

The metal line may be made of copper, aluminum, silver, or gold.

The internal insulating material and the external insulating material may be made of different materials.

According to still another preferred embodiment of the present invention, there is provided a semiconductor package, including: a substrate formed with a double-sided mounting electrode; a plurality of electronic elements mounted on both surfaces of the substrate; and external connection terminals each bonded to an outer side of a lower surface of the substrate, wherein the external connection terminal includes an internal insulating material, an external insulating material, and metal lines which are formed between the internal insulating material and the external insulating material.

The metal lines may be formed to be exposed on upper and lower surfaces of the internal insulating material and the external insulating material.

The semiconductor package may further include: a solder ball formed in the external connection terminal.

The semiconductor package may further include: molding parts formed on both surfaces of the substrate to cover electronic elements mounted on both surfaces of the substrate.

The semiconductor package may further include: a molding part formed over the lower surface of the substrate to cover the electronic elements mounted on the lower surface of the substrate and the external connection terminal.

According to still yet another preferred embodiment of the present invention, there is provided a method of manufacturing a semiconductor package, including: mounting a plurality of electronic elements on an upper surface of a substrate on which a double-sided mounting electrode is formed; mounting a plurality of electronic elements on a lower surface of the substrate; and bonding each of the external connection terminals to an outer side of a lower surface of the substrate, wherein the external connection terminal includes an internal insulating material, an external insulating material, and metal lines which are formed between the internal insulating material and the external insulating material.

The method of manufacturing a semiconductor package may further include: after the mounting of the electronic elements on the upper surface of the substrate, forming a molding part on the upper surface of the substrate to cover the electronic elements mounted on the upper surface of the substrate and the whole of the upper surface of the substrate.

The method of manufacturing a semiconductor package may further include: after the mounting of the electronic elements on the lower surface of the substrate, forming a molding part on the lower surface of the substrate to cover the whole of the electronic elements mounted on the lower surface of the substrate.

The method of manufacturing a semiconductor package may further include: prior to the bonding of each of the external connection terminals to the outer side of the lower surface of the substrate, polishing the metal lines to be exposed on the upper and lower surfaces of the internal insulating material and the external insulating material of the external connection terminal.

The method of manufacturing a semiconductor package may further include: after the bonding of each of the external connection terminal to the outer side of the lower surface of the substrate, forming a molding part over the lower surface of the substrate to cover the electronic elements mounted on the lower surface of the substrate and the external connection terminal.

The method of manufacturing a semiconductor package may further include: forming a solder ball in the external connection terminal.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a three-dimensional diagram illustrating a structure of an external connection terminal according to a preferred embodiment of the present invention;

FIG. 2 is a plan view illustrating the structure of the external connection terminal according to a preferred embodiment of the present invention;

FIG. 3 is a plan view illustrating a structure of an external connection terminal according to another preferred embodiment of the present invention;

FIG. 4 is a cross-sectional view illustrating a semiconductor package structure according to a preferred embodiment of the present invention;

FIGS. 5 to 9 are flow charts sequentially illustrating a method of manufacturing an external connection terminal according to another preferred embodiment of the present invention; and

FIGS. 10 to 15 are flow charts sequentially illustrating a method of manufacturing a semiconductor package according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

External Connection Terminal

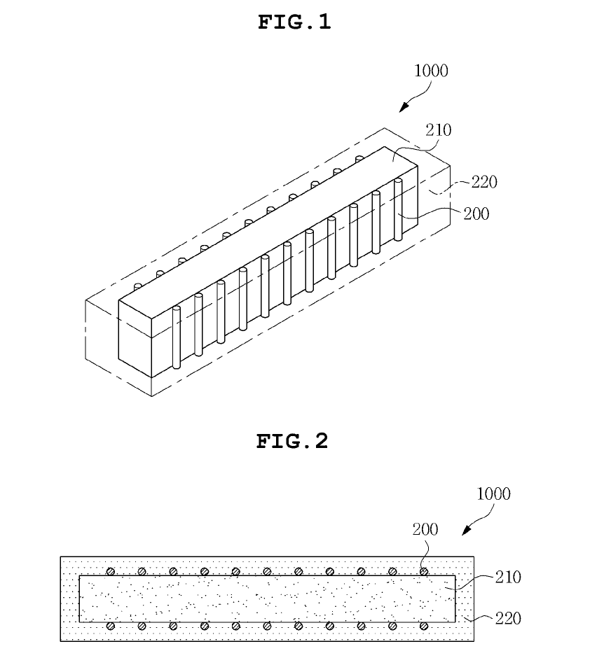

FIG. 1 is a three-dimensional diagram illustrating a structure of an external connection terminal according to a preferred embodiment of the present invention.

As illustrated in FIG. 1, an external connection terminal 1000 includes an internal insulating material 210, an external insulating material 220 which is formed to enclose the internal insulating material 210, and metal lines 200 which are formed between the internal insulating material 210 and the external insulating material 220.

Herein, upper and lower surfaces of the insulating materials 210 and 220 may be formed to expose the metal lines 200.

Further, the internal insulating material 210 and the external insulating material 220 may be made of different materials, and for example, the internal insulating material 210 may be made of a thermosetting resin such as epoxy resin and a thermoplastic resin such as polyimide, but is not particularly limited thereto.

In this case, an insulating material having a small coefficient of thermal expansion (CTE) may be selectively used.

Further, as the external insulating material 220, any material which is known in the art and facilitates encapsulation may be used. For example, an epoxy molded compound (EMC) may be used.

In this case, the internal insulating material 210 having a small coefficient of thermal expansion is used and thus has the reduced deformation due to heat, thereby increasing reliability of a product.

Herein, even though the coefficient of thermal expansion (CTE) of the external insulating material 220 is larger than that of the internal insulating material 210, the overall deformation of the external connection terminal may be reduced due to rigidity of the internal insulating material 210.

Herein, the metal line 200 may be made of copper, aluminum, silver, or gold, but is not particularly limited thereto.

FIG. 2 is a plan view of the external connection terminal 1000 according to a preferred embodiment of the present invention.

As illustrated in FIG. 2, the metal lines 200 may be exposed on an upper portion of the external connection terminal.

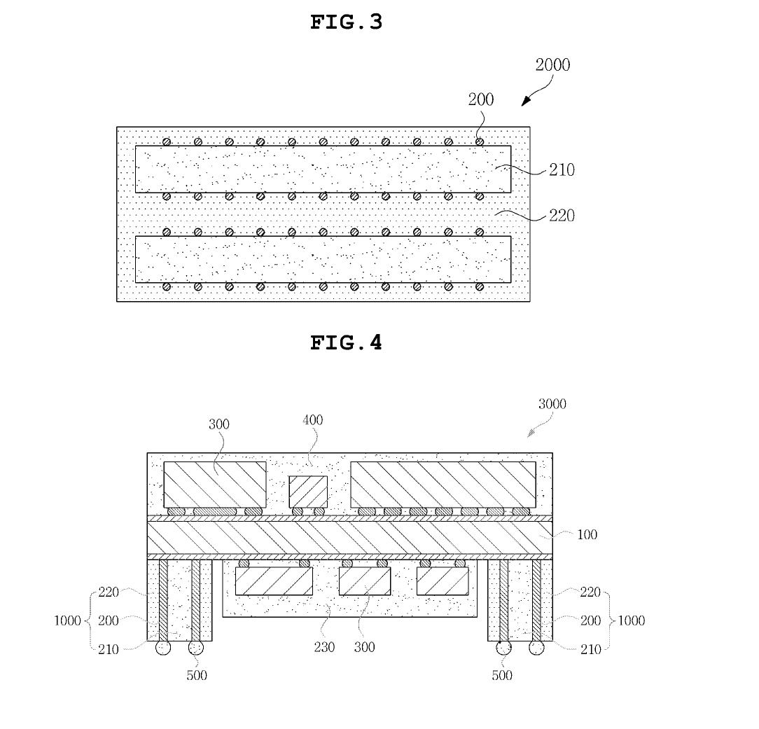

FIG. 3 is a plan view of an external connection terminal 2000 according to another preferred embodiment of the present invention.

As illustrated in FIG. 3, an external connection terminal 2000 includes the internal insulating material 210, the external insulating material 220 which is formed to enclose the internal insulating material 210, and the metal lines 200 which are formed between the internal insulating material 210 and the external insulating material 220.

Herein, the upper and the lower surfaces of the insulating materials 210 and 220 may be formed to expose the metal lines 200.

In this case, the external insulating material 220 may be formed to cover the plurality of internal insulating materials 220 including the metal lines 200.

Semiconductor Package

FIG. 4 is a cross-sectional view of a semiconductor package structure according to a preferred embodiment of the present invention.

As illustrated in FIG. 4, a semiconductor package 300 having the external connection terminals 1000 includes the substrate 100 on which a double-sided mounting electrode is formed, a plurality of electronic elements 300 which are mounted on both surfaces of the substrate 100, and the external connection terminals 1000 which are each bonded to an outer side of the lower surface of the substrate 100, in which the external connection terminal 1000 includes the internal insulating material 210, the external insulating material 220, and the metal lines 200 formed between the insulating materials.

The substrate 100 may be a printed circuit board, a ceramic substrate, and a metal substrate having an anodized layer, but is not particularly limited thereto.

The substrate 100 is a circuit board in which at least one layer of circuit including a connection pad is formed on an insulating layer thereof and may preferably be the printed circuit board. For convenience of explanation, FIG. 4 does not illustrate a configuration of an inner layer circuit, but it may be sufficiently recognized by those skilled in the art that a general circuit board as the substrate may be used.

The ceramic substrate may be made of metal based nitride or a ceramic material. Here, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal substrate may be made of for example, aluminum (Al) which is a metal material capable of being easily obtained at a relatively low cost and has significantly excellent heat transfer characteristics, or an alloy thereof.

In addition, the anodized layer which is formed by immersing the metal substrate made of aluminum or an alloy thereof in an electrolyte solution such as boric acid, phosphoric acid, sulfuric acid, chromic acid, or the like, and then applying an anode to the metal substrate and applying a cathode to the electrolyte solution, has insulation characteristics and relatively high heat transfer characteristics of about 10 to 30 W/mk.

As described above, the anodized layer made of aluminum or an alloy thereof may be an aluminum anodized layer (Al₂O₃).

Since the anodized layer has insulation characteristics, it enables a circuit layer to be formed on the substrate 100. In addition, since the anodized layer may be formed at a thickness thinner than that of a general insulation layer, it enables thinness simultaneously with further improving heat radiating performance.

Here, an electronic element 300 includes various elements such as a passive element and an active element and any element which may be mounted on the substrate may be used as an electronic element.

FIG. 4 does not illustrate in detail other components of the element but schematically illustrates other components, but it may be sufficiently recognized by those skilled in the art that the semiconductor element having all the structure known in the art may be applied to the printed circuit board in which the semiconductor element of the present invention is embedded.

Herein, the upper and lower surfaces of the insulating materials 210 and 220 of the external connection terminal 1000 may be formed to expose the metal lines 200.

A solder ball 500 may be further formed on the exposed metal line 200.

Molding parts 230 and 400 may be formed on both surfaces of the substrate 100 to cover the electronic elements 300 which are mounted on both surfaces of the substrate 100.

The molding parts 230 and 400 increase an adhesion between the molding material and the substrate, such that the occurrence of a problem such as delamination between the substrate and the molding material is reduced, thereby improving the long-term reliability of the substrate.

Further, heat shielding due to the molding is made and therefore a heat sink effect may be more improved.

In this case, as the molding material, a silicon gel, an epoxy molding compound (EMC), and the like, may be used, but the preferred embodiment of the present invention is not particularly limited thereto.

Further, the internal insulating material 210 and the external insulating material 220 of the external connection terminal may be made of different materials, and for example, the internal insulating material 210 may be made of a thermosetting resin such as epoxy resin and a thermoplastic resin such as polyimide, but is not particularly limited thereto.

In this case, an insulating material having a small coefficient of thermal expansion (CTE) may be selectively used.

Further, as the external insulating material 220 of the external connection terminal, any material which is known in the art and facilitates encapsulation may be used. For example, an epoxy molded compound (EMC) may be used.

In this case, the internal insulating material 210 having a small coefficient of thermal expansion is used and thus has the reduced deformation due to heat, thereby increasing reliability of a product.

Herein, even though the coefficient of thermal expansion (CTE) of the external insulating material 220 is larger than that of the internal insulating material 210, the overall deformation of the external connection terminal may be reduced due to rigidity of the internal insulating material 210.

Herein, the metal line 200 may be made of copper, aluminum, silver, or gold, but is not particularly limited thereto.

Method of Manufacturing External Connection Terminal

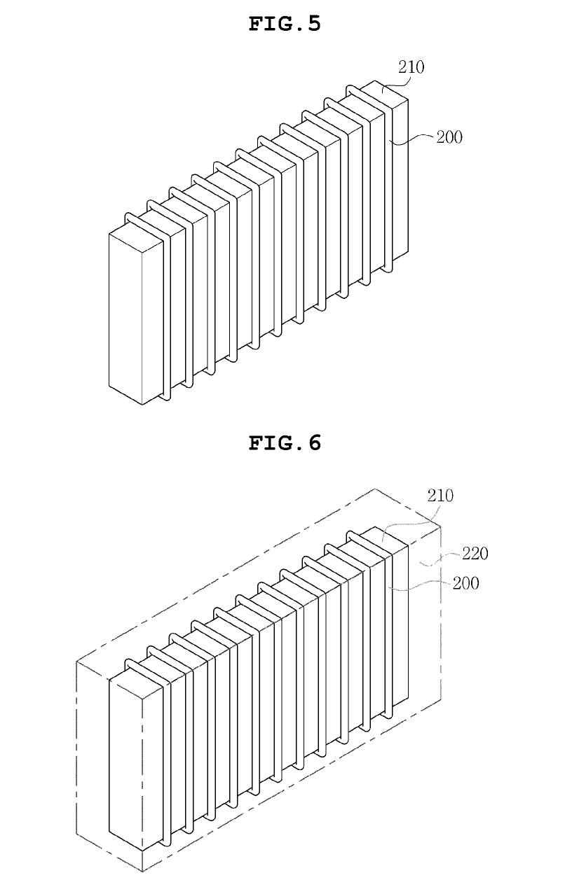

FIGS. 5 to 9 are flow charts sequentially illustrating a method of manufacturing an external connection terminal 1000 according to another preferred embodiment of the present invention.

As illustrated in FIG. 5, the metal lines 200 are formed on the internal insulating material 210.

In this case, the metal lines 200 may be wound in one direction to enclose the internal insulating material 210 by a coiling method.

Here, the interval of the metal lines 200 may be arbitrarily defined at the time of coiling.

Further, the metal line 200 may be made of copper, aluminum, silver, or gold, but is not particularly limited thereto.

As illustrated in FIG. 6, the external insulating material 220 may be formed to enclose the internal insulating material 210 formed with the metal lines 200.

In this case, the internal insulating material 210 and the external insulating material 220 may be made of different materials, and for example, the internal insulating material 210 may be made of a thermosetting resin such as epoxy resin and a thermoplastic resin such as polyimide, but is not particularly limited thereto.

In this case, an insulating material having a small coefficient of thermal expansion (CTE) may be selectively used.

Further, as the external insulating material 220, any material which is known in the art and facilitates encapsulation may be used. For example, an epoxy molded compound (EMC) may be used.

In this case, the internal insulating material 210 having a small coefficient of thermal expansion is used and thus has the reduced deformation due to heat, thereby increasing reliability of a product.

Herein, even though the coefficient of thermal expansion (CTE) of the external insulating material is larger than that of the internal insulating material 210, the overall deformation of the external connection terminal may be reduced due to rigidity of the internal insulating material 210.

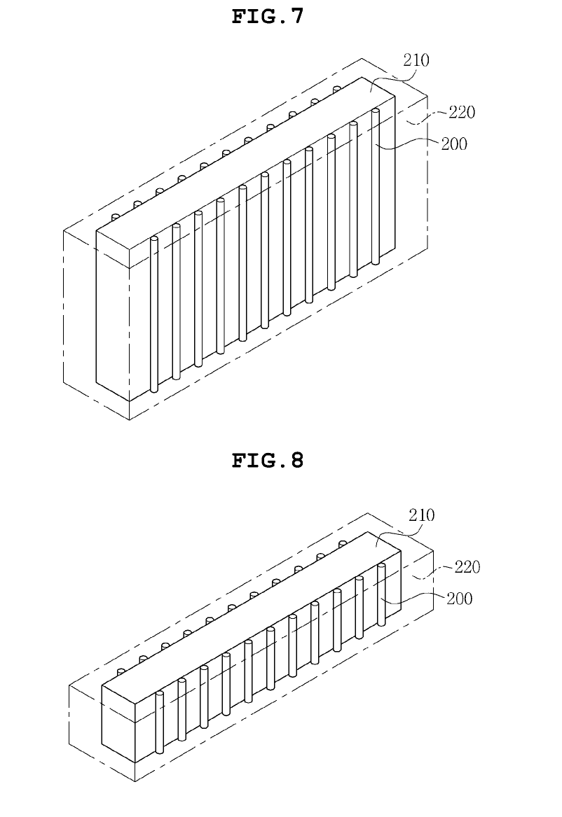

As illustrated in FIG. 7, the metal lines 200 are polished to be exposed on the upper and lower surfaces of the insulating materials 210 and 220.

As illustrated in FIG. 8, the external connection terminal may be cut in a plurality of units as the size which is required by those skilled in the art.

In this case, the size of the unit may be variously applied.

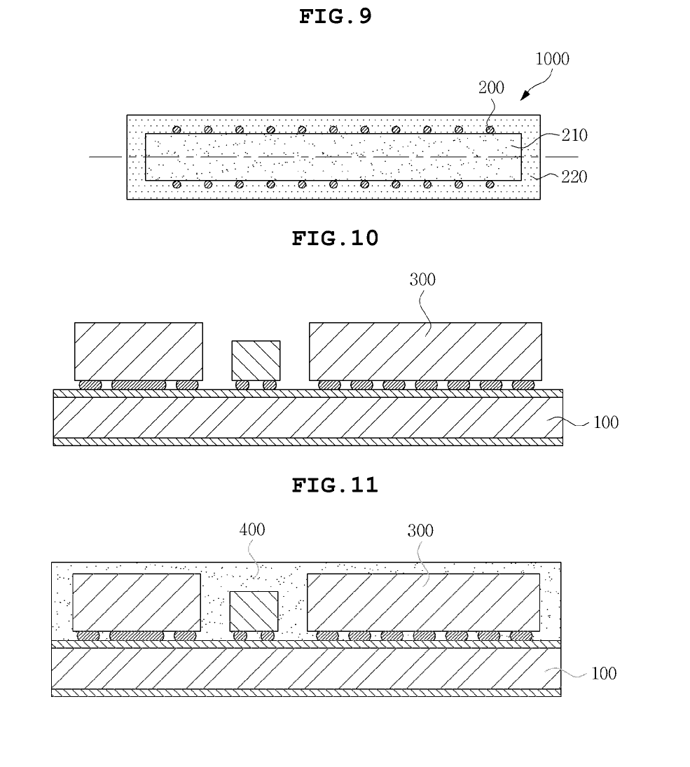

As illustrated in FIG. 9, the external connection terminal may be cut vertically.

In this case, the cut size and form may be variously applied.

Herein, the method of manufacturing an external connection terminal 1000 may be easily mass produced and the external connection terminal 1000 may be cut and used as desired.

Further, as the coiling method is applied, the process may be simplified and the process costs may be saved.

Method of Manufacturing Semiconductor Package

FIGS. 10 to 15 are flow charts sequentially illustrating a method of manufacturing a semiconductor package according to another preferred embodiment of the present invention.

As illustrated in FIG. 10, the substrate 100 on which a double-sided mounting electrode is formed is prepared and then the plurality of electronic elements 300 is mounted on the upper surface of the substrate 100.

The substrate 100 may be a printed circuit board, a ceramic substrate, and a metal substrate having an anodized layer, but is not particularly limited thereto.

The substrate 100 is a circuit board in which at least one layer of circuit including a connection pad is formed on an insulating layer thereof and may preferably be the printed circuit board. For convenience of explanation, FIG. 10 does not illustrate a configuration of an inner layer circuit, but it may be sufficiently recognized by those skilled in the art that a general circuit board as the substrate may be used.

The ceramic substrate may be made of metal based nitride or a ceramic material. Here, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal substrate may be made of for example, aluminum (Al) which is a metal material capable of being easily obtained at a relatively low cost and has significantly excellent heat transfer characteristics, or an alloy thereof.

In addition, the anodized layer which is formed by immersing the metal substrate made of aluminum or an alloy thereof in an electrolyte solution such as boric acid, phosphoric acid, sulfuric acid, chromic acid, or the like, and then applying an anode to the metal substrate and applying a cathode to the electrolyte solution, has insulation characteristics and relatively high heat transfer characteristics of about 10 to 30 W/mk.

As described above, the anodized layer made of aluminum or an alloy thereof may be an aluminum anodized layer (Al₂O₃).

Since the anodized layer has insulation characteristics, it enables a circuit layer to be formed on the substrate 100. In addition, since the anodized layer may be formed at a thickness thinner than that of a general insulation layer, it enables thinness simultaneously with further improving heat radiating performance.

Here, an electronic element 300 includes various elements such as a passive element and an active element and any element which may be mounted on the substrate may be used as an electronic element.

FIG. 10 does not illustrate in detail other components of the element but schematically illustrates other components, but it may be sufficiently recognized by those skilled in the art that the semiconductor element having all the structure known in the art may be applied to the printed circuit board in which the semiconductor element of the present invention is embedded.

As illustrated in FIG. 11, the molding part 400 may be formed to cover the electronic element 300 mounted on the upper surface of the substrate 100.

The molding part 400 increases an adhesion between the molding material and the substrate, such that the occurrence of a problem such as delamination between the substrate and the molding material is reduced, thereby improving the long-term reliability of the substrate.

Further, heat shielding due to the molding is made and therefore a heat sink effect may be more improved.

In this case, as the molding material, a silicon gel, an epoxy molding compound (EMC), and the like, may be used, but the preferred embodiment of the present invention is not particularly limited thereto.

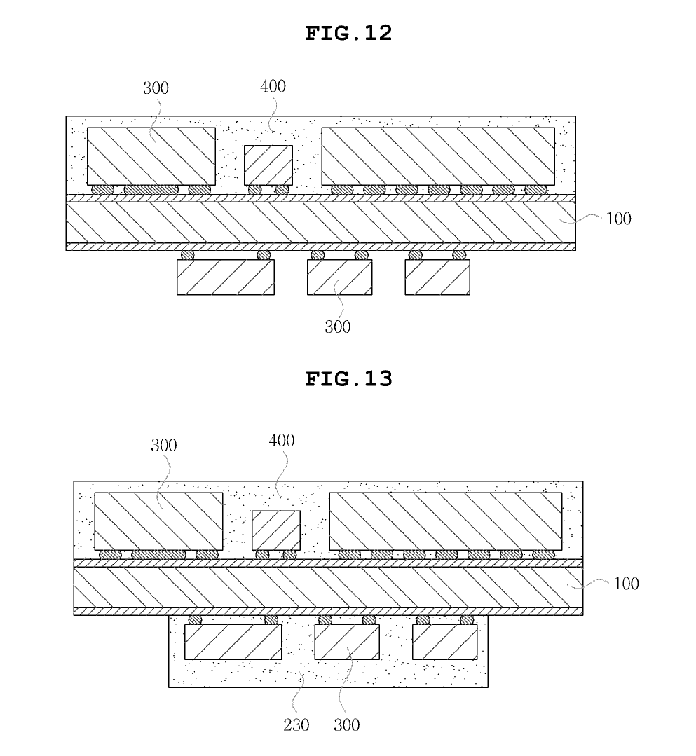

As illustrated in FIG. 12, the plurality of electronic elements 300 may be mounted on the lower surface of the substrate 100.

As illustrated in FIG. 13, the molding part 230 may be formed to cover the plurality of mounted electronic elements 300.

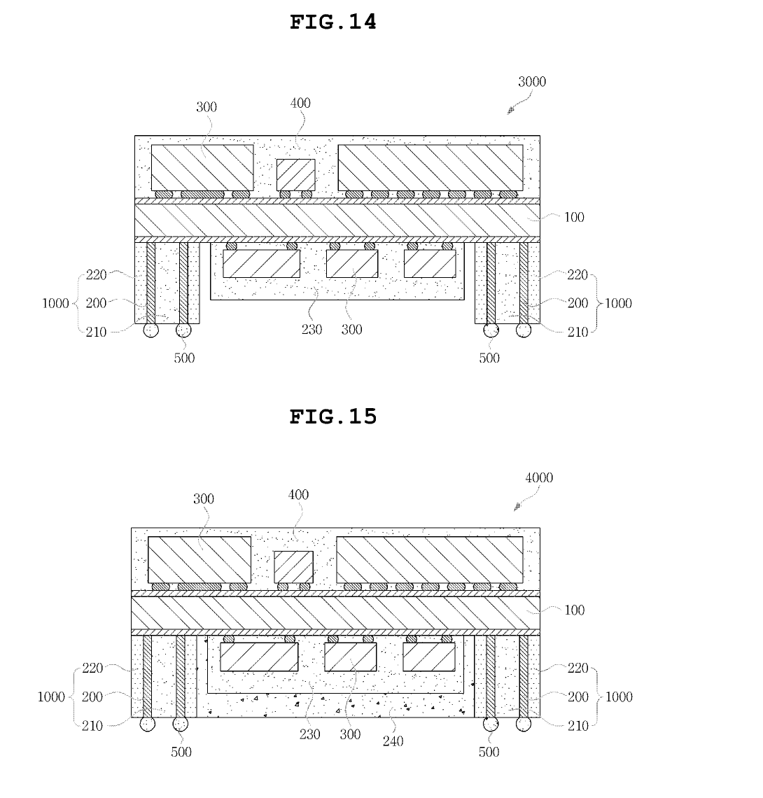

As illustrated in FIG. 14, the external connection terminals 1000 may be each bonded to an outer side of the lower surface of the substrate 100.

Here, the external connection terminal 1000 is bonded to the substrate 100 by the soldering, the bonding material, or these two methods.

Further, the soldering may be made by using a Sn—Pb eutectic solder or a lead free solder such as Sn—Ag—Cu. Further, the soldering method may be formed of a solder paste applying process using a metal mask. However, the soldering method is not limited thereto.

Further, the lower end of the external connection terminal 1000 may be formed with a solder ball 500.

As illustrated in FIG. 15, the molding part 240 may be formed over the lower surface of the substrate 100 to cover the electronic element 300 mounted on the lower surface of the substrate 100 and the external connection terminal 1000.

According to the insulating material, the semiconductor package having the insulating material, and the method of manufacturing the same in accordance with the preferred embodiments of the present invention, it is possible to reduce the deformation due to heat by using the material in which the CTEs of insulating materials inside and outside the external connection terminal are different.

Further, it is possible to facilitate the manufacturing of the external connection terminal using the coiling method.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An external connection terminal, comprising:
an internal insulating material;
an external insulating material formed to enclose the internal insulating material; and
metal lines formed between the internal insulating material and the external insulating material.

2. The external connection terminal as set forth in claim 1, wherein the metal lines are formed to be exposed on upper and lower surfaces of the internal insulating material and the external insulating material.

3. The external connection terminal as set forth in claim 1, wherein the metal line is made of copper, aluminum, silver, or gold.

4. The external connection terminal as set forth in claim 1, wherein the internal insulating material and the external insulating material are made of different materials.

5. A method of manufacturing an external connection terminal, comprising:
preparing an internal insulating material;
forming metal lines on the internal insulating material; and
forming an external insulating material to enclose the internal insulating material and the metal lines.

6. The method as set forth in claim 5, further comprising:
after the forming of the external insulating material, polishing the metal lines to be exposed on upper and lower surfaces of the internal insulating material and the external insulating material.

7. The method as set forth in claim 5, wherein the forming of the metal lines on the internal insulating material includes performing coiling.

8. The method as set forth in claim 5, further comprising:
after the forming of the external insulating material, cutting the internal insulating material and the external insulating material in a plurality of units.

9. The method as set forth in claim 5, wherein the metal line is made of copper, aluminum, silver, or gold.

10. The method as set forth in claim 5, wherein the internal insulating material and the external insulating material are made of different materials.

11. A semiconductor package, comprising:
a substrate formed with a double-sided mounting electrode;
a plurality of electronic elements mounted on both surfaces of the substrate; and
external connection terminals each bonded to an outer side of a lower surface of the substrate,
wherein the external connection terminal includes an internal insulating material, an external insulating material, and metal lines which are formed between the internal insulating material and the external insulating material.

12. The semiconductor package as set forth in claim 11, wherein the metal lines are formed to be exposed on upper and lower surfaces of the internal insulating material and the external insulating material.

13. The semiconductor package as set forth in claim 11, further comprising:
a solder ball formed in the external connection terminal.

14. The semiconductor package as set forth in claim 11, further comprising:
molding parts formed on both surfaces of the substrate to cover electronic elements mounted on both surfaces of the substrate.

15. The semiconductor package as set forth in claim 11, further comprising:
a molding part formed over the lower surface of the substrate to cover the electronic elements mounted on the lower surface of the substrate and the external connection terminal.

16. A method of manufacturing a semiconductor package, comprising:
mounting a plurality of electronic elements on an upper surface of a substrate on which a double-sided mounting electrode is formed;
mounting a plurality of electronic elements on a lower surface of the substrate; and
bonding each of the external connection terminals to an outer side of a lower surface of the substrate,
wherein the external connection terminal includes an internal insulating material, an external insulating material, and metal lines which are formed between the internal insulating material and the external insulating material.

17. The method as set forth in claim 16, further comprising:
after the mounting of the electronic elements on the upper surface of the substrate, forming a molding part on the upper surface of the substrate to cover the electronic elements mounted on the upper surface of the substrate and the whole of the upper surface of the substrate.

18. The method as set forth in claim 16, further comprising:
after the mounting of the electronic elements on the lower surface of the substrate, forming a molding part on the lower surface of the substrate to cover the whole of the electronic elements mounted on the lower surface of the substrate.

19. The method as set forth in claim 16, further comprising:
prior to the bonding of each of the external connection terminals to the outer side of the lower surface of the substrate, polishing the metal lines to be exposed on the upper and lower surfaces of the internal insulating material and the external insulating material of the external connection terminal.

20. The method as set forth in claim 16, further comprising:
after the bonding of each of the external connection terminal to the outer side of the lower surface of the substrate, forming a molding part over the lower surface of the substrate to cover the electronic elements mounted on the lower surface of the substrate and the external connection terminal.

21. The method as set forth in claim 16, further comprising:
forming a solder ball in the external connection terminal.
